(19) United States
(12) Patent Application Publication
(10) Pub. No.: US 2017/0301368 A1
(43) Pub. Date: Oct. 19, 2017

(54) MANUFACTURING METHOD FOR MAGNETIC RECORDING MEDIUM AND MAGNETIC RECORDING MEDIUM MANUFACTURED BY SAID MANUFACTURING METHOD

(71) Applicants: FUJI ELECTRIC CO., LTD., Kawasaki-shi (JP); TOHOKU UNIVERSITY, Sendai-shi (JP)

(72) Inventors: Hiroto Kikuchi, Matsumoto-shi (JP); Takehito Shimatsu, Sendai-shi (JP)

(21) Appl. No.: 15/640,957

(22) Filed: Jul. 3, 2017

Related U.S. Application Data
(63) Continuation of application No. PCT/JP2016/002901, filed on Jun. 15, 2016.

(30) Foreign Application Priority Data
Jul. 2, 2015 (JP) 2015-133929

(51) Int. Cl. G11B 5/851; G11B 5/84; C23C 14/14; G11B 5/65; C23C 14/34; G11B 5/66; G11B 5/82; G11B 5/00

(52) U.S. Cl. CPC G11B 5/851; G11B 5/66; G11B 5/8404; G11B 5/82; C23C 14/14; G11B 5/653; C23C 14/3464; G11B 2005/0021

(57) ABSTRACT

The present invention is a method for mass-production of a recording medium with the component composition thereof monotonically changing along the film thickness direction. In the method, the magnetic recording medium that includes at least a substrate, and first magnetic recording layer and second magnetic recording layer as the magnetic recording layer. The method includes: laminating a second magnetic layer of FePtRh on a first magnetic layer of FePt or FePtRh with heating. In the method, heat treatment may be preheat-treatment or postheat-treatment, when laminating the second magnetic layer of FePtRh onto the first magnetic layer of FePtRh, the concentration of Rh in the second magnetic layer is higher than that of the first magnetic layer.

### CROSS-REFERENCE TO RELATED APPLICATIONS

This application is a continuation application of PCT Application No. PCT/JP2016/002901 filed on Jun. 15, 2016 under 37 Code of Federal Regulation §1.53 (b) and the PCT application claims the benefit of Japanese Patent Application No. 2015-133929 filed on Jul. 2, 2015, all of the above applications being hereby incorporated by reference wherein in their entirety.

### BACKGROUND OF THE INVENTION

### Field of the Invention

The present invention relates to a manufacturing method for a magnetic recording medium, and a magnetic recording medium manufactured by the manufacturing method.

### Description of the Related Art

Recently, higher density magnetic recording is in high demand. As a technology for realizing the high density of the magnetic recording, a perpendicular magnetic recording method is employed. The perpendicular magnetic recording medium includes at least a non-magnetic substrate and a magnetic recording layer formed from a hard magnetic material. The perpendicular magnetic recording medium may further include, optionally, a soft magnetic underlayer which is formed from a soft magnetic material and plays a role of concentrating a magnetic flux generated by a magnetic head on the magnetic recording layer, an underlayer for orienting the hard magnetic material of the magnetic recording layer in an intended direction, a protective film for protecting a surface of the magnetic recording layer and the like.

In order to make the density of magnetic recording high, high thermal stability is necessary, and therefore there is a need for a magnetic recording layer constituted from a material having high magnetic anisotropy such as FePt. However, FePt has high coercive force at room temperature, and with an ordinary recording head, recording cannot be performed because a magnetic field is insufficient. Therefore, a heat-assisted magnetic recording method is proposed.

A heat-assisted magnetic recording method is a recording method in which a magnetic recording layer is irradiated with laser to heat and lower the coercive force, and, in the state, the magnetic field for recording is applied to reverse magnetization. In a heat-assisted magnetic recording method, a magnetic material is heated to near the Curie temperature and is recorded. For example, it is known that the Curie temperature (Tc) of FePt is around 470° C.

On the other hand, recording at high temperatures brings about deterioration of a carbon protective film for protecting a magnetic recording layer or a lubricant on a protective film to be a cause of deterioration of the recording head itself, which becomes, therefore, a factor that significantly lowers the reliability of a magnetic recording device. Accordingly, it is desired to perform recording at temperature as low as possible.

In Chen et al., J. Phys. D: Appl. Phys., 43 (2010) 185001, it is reported that a recording magnetic field (coercive force) may be lowered while keeping thermal stability by a magnetic recording layer having inclined magnetic anisotropy (Ku), in which a lower layer having high Ku, a middle layer having middle Ku and an upper layer having low Ku, are laminated in this order. In Zha et al., Appl. Phys. Lett., 97 182504 (2010), it is reported that a recording magnetic field (coercive force) may be lowered by having a magnetic layer comprised of an (FePt)₁₀₀₋ₓCuₓ alloy in which Ku is inclined by reducing monotonically the Cu content x from the lower layer toward the upper layer.

### SUMMARY OF THE INVENTION

In Zha et al., Appl. Phys. Lett., 97 182504 (2010), a magnetic recording layer is formed by a co-sputtering method by use of Fe, Pt and Cu targets, and, in order to incline the Cu content in a film thickness direction, the sputtering power for Cu is changed with time. However, in a co-sputtering method, control of a composition ratio is difficult, and thus it is difficult to make stable production.

On the other hand, in a step for mass-production of a magnetic recording medium, a deposition method with high throughput is employed wherein a plurality of deposition chambers are aligned and each of layers of the magnetic recording medium, in the deposition chambers, is formed one by one with transfer of a substrate. In the mass-production step, for example, when an FePtCu film is deposited, a magnetic recording layer is deposited by use of an alloy target of FePtCu in a deposition chamber of an FePtCu film. In this case, it is very difficult to provide inclination in the composition of Cu in a deposited magnetic recording layer by changing the composition of Cu only. In order to incline the composition of Cu in such deposition in a mass-production step, it is necessary to prepare a plurality of FePtCu alloy targets in which compositions are previously changed, and to laminate FePtCu films by arranging targets so that the composition of Cu in the magnetic recording layer will be change gradually. However, in order to realize such a step, many deposition chambers are required, and thus the production efficiency lowered.

Therefore, it is desired to provide a method suitable to mass-production for manufacturing a magnetic recording medium in which the composition of components in the magnetic recording medium changes monotonically in a thickness direction.

A manufacturing method for a magnetic recording medium according to an embodiment is for manufacturing a magnetic recording medium comprising at least a substrate and a magnetic recording layer, in which the magnetic recording layer comprises Fe, Pt and Rh, and composition of Rh in the magnetic recording layer changes in a thickness direction of the magnetic recording layer, comprising: (1) a first deposition step of forming a first magnetic layer comprising Fe and Pt, or Fe, Pt and Rh; (2) a second deposition step of forming a second magnetic layer comprising Fe, Pt and Rh, the second magnetic layer, when the first magnetic layer comprises Rh, being formed so as to comprise Rh in concentration higher than that in the first magnetic layer; and (3) subsequent to the first deposition step and second deposition step, a heating step of the substrate with the first and second magnetic layers previously formed. Here, heating temperature in the heating step of (3) is preferably 400° C. or higher.

The manufacturing method for a magnetic recording medium according to another embodiment is for manufacturing a magnetic recording medium comprising at least a substrate and a magnetic recording layer, in which the magnetic recording layer comprises Fe, Pt and Rh, and composition of Rh in the magnetic recording layer changes in a thickness direction of the magnetic recording layer. The method comprises: (i) a heating step of heating the substrate; (ii) a first deposition step of forming a first magnetic layer comprising Fe and Pt, or Fe, Pt and Rh; and (iii) a second deposition step of forming a second magnetic layer comprising Fe, Pt and Rh, the second magnetic layer, when the first magnetic layer comprises Rh, being formed so as to comprise Rh in concentration higher than that in the first magnetic layer, wherein a heating step is performed prior to the first deposition step and the second deposition step. Here, heating temperature of a substrate in a heating step of (i) is preferably 400° C. or higher.

The manufacturing method for a magnetic recording medium according to yet another embodiment is for manufacturing a magnetic recording medium comprising at least a substrate and a magnetic recording layer, in which the magnetic recording layer comprises Fe, Pt and Rh, and composition of Rh in the magnetic recording layer changes in a thickness direction of the magnetic recording layer. The method comprises: (A) a first deposition step of forming a first magnetic layer comprising Fe and Pt, or Fe, Pt and Rh with heating of the substrate from a back surface; and (B) a second deposition step of forming a second magnetic layer comprising Fe, Pt and Rh with heating of a substrate from a back surface, the second magnetic layer, when the first magnetic layer comprises Rh, being formed so as to comprise Rh in concentration higher than that in the first magnetic layer. Here, heating temperatures of the substrate in the step (A) and the step (B) are preferably 400° C. or higher.

The magnetic recording media are magnetic recording media manufactured by above-described three manufacturing methods.

A magnetic recording medium in which the composition of components in the magnetic recording medium changes monotonically in a film thickness direction may be manufactured by mass-production.

Further features of the present invention will become apparent from the following description of exemplary embodiments (with reference to the attached drawings).

### BRIEF DESCRIPTION OF THE DRAWINGS

FIG. 1 is a cross-sectional view of a structural example of a magnetic recording medium;

FIG. 2 is a perspective view showing change in a state of a magnetic recording layer of a magnetic recording medium;

FIG. 3 is a perspective view showing an example of a method for preparing a magnetic recording layer of a magnetic recording medium;

FIG. 4 is a perspective view showing an example of a method for preparing a magnetic recording layer of a magnetic recording medium;

FIG. 5 is a graph showing the relationship between the addition amount of X in a magnetic recording layer using FePtX (X is Rh, Cu or Ru), and Ku at 230° C.;

FIG. 6A is a drawing for describing a procedure for measuring a concentration distribution of X in a magnetic recording layer using FePtX (X is Rh or Ru);

FIG. 6B is a graph for describing a procedure for measuring a concentration distribution of X in a magnetic recording layer using FePtX (X is Rh or Ru); and

FIG. 7 is a graph showing the relationship between a diffusion distance and heating time for deposition in a magnetic recording layer using FePtX (X is Rh or Ru).

### DESCRIPTION OF THE EMBODIMENTS

Hereinafter, a manufacturing method for a magnetic recording medium and a magnetic recording medium manufactured by the manufacturing method will be described with reference to the drawings. The following description is merely an exemplification, and is not intended to limit the invention of the present application.

The manufacturing method for the magnetic recording medium is for manufacturing a magnetic recording medium comprising at least a substrate and a magnetic recording layer, in which the magnetic recording layer comprises Fe, Pt and Rh and the composition of Rh in the magnetic recording layer changes in a thickness direction of the magnetic recording layer.

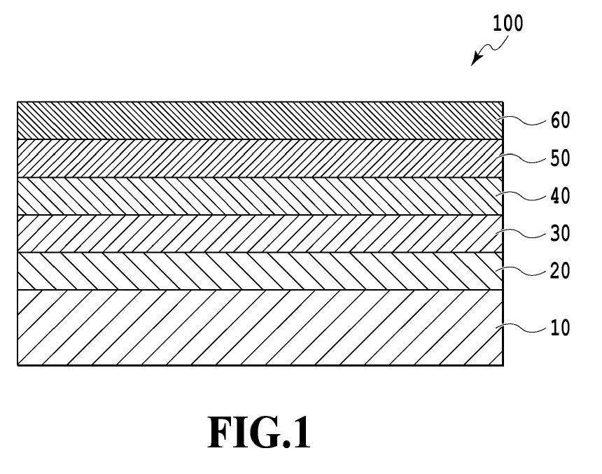

Here, the magnetic recording medium manufactured by the above-described manufacturing method comprises at least a substrate and a magnetic recording layer, and may further comprise, between these layers, layers or a layer known in the art such as an adhesion layer, a soft magnetic underlayer, a heat-sink layer, an underlayer and/or a seed layer. In addition, the magnetic recording medium may further comprise layers or a layer known in the art such as a protective layer and/or a liquid-lubricant layer, on the magnetic recording layer. FIG. 1 shows a structural example of a magnetic recording medium 100 comprising a substrate 10, an adhesion layer 20, an underlayer 30, a seed layer 40, a magnetic recording layer 50, and a protective layer 60. The magnetic recording layer 50 of the magnetic recording medium 100 comprises Fe, Pt and Rh, and the composition of Rh in the magnetic recording layer changes in a thickness direction of magnetic recording layer. For example, the magnetic recording medium has a magnetic recording layer having such a concentration gradient where the concentration of Rh increases from the substrate 10 side of the magnetic recording layer 50 toward the protective layer 60 side.

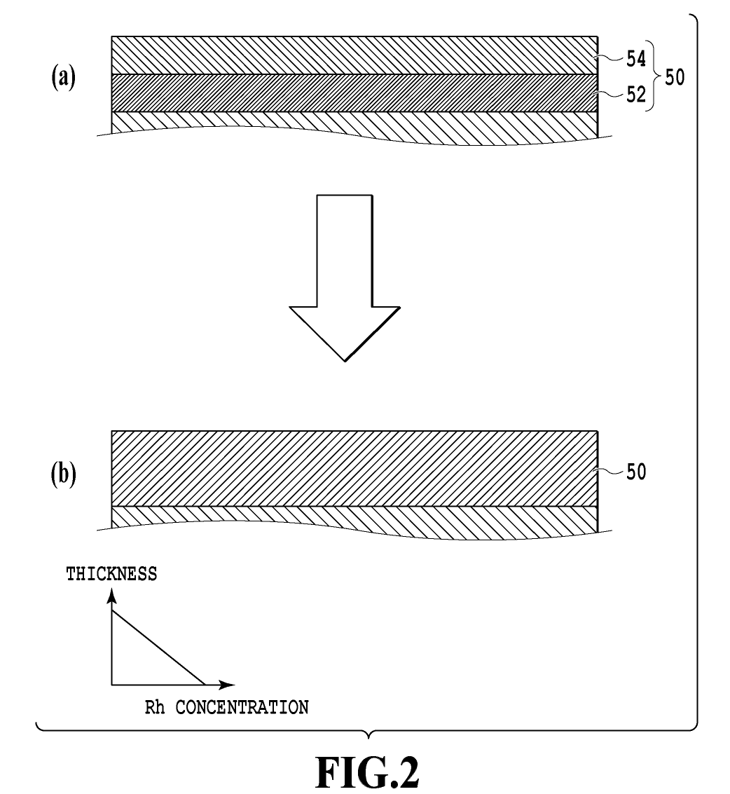

In the manufacturing method for a magnetic recording medium, for example, as shown in FIG. 2, a first magnetic layer 52 and a second magnetic layer 54 are formed on the substrate 10, and a predetermined element in the magnetic layer is diffused into the first magnetic layer to give a gradient to the composition of the predetermined element in the thickness direction of the magnetic recording layer 50.

The manufacturing method for a magnetic recording medium is characterized by comprising: (1) a first deposition step of forming a first magnetic layer comprising Fe and Pt, or Fe, Pt and Rh on the substrate; (2) a second deposition step of forming a second magnetic layer comprising Fe, Pt and Rh on the first magnetic layer, the second magnetic layer, when the first magnetic layer comprises Rh, being formed so as to comprise Rh in concentration higher than that in the first magnetic layer; and (3) subsequent to the first deposition step and the second deposition step, a heating step of the substrate with the first and second magnetic layers previously formed.

In the description and claims, the term “inclination” means that the composition of an element to be an object of the magnetic recording layer (such as Rh, Cu, Ru, for example), or magnetic anisotropy (Ku) of the magnetic recording layer changes monotonically in a thickness direction of the magnetic recording layer. For example, a magnetic recording layer in which the composition of an element to be an object changes monotonically from the substrate side of the magnetic recording layer toward the protective layer side is called a magnetic recording layer in which an element to be an object “inclines.” For example, a magnetic recording layer in which the composition of Rh increases monotonically in a thickness direction of the magnetic recording layer is called a magnetic recording layer in which “the composition of Rh inclines,” etc. Further, a magnetic recording layer in which Ku changes monotonically from the substrate side of the magnetic recording layer toward the protective layer side is called as a magnetic recording layer in which “Ku inclines,” etc.

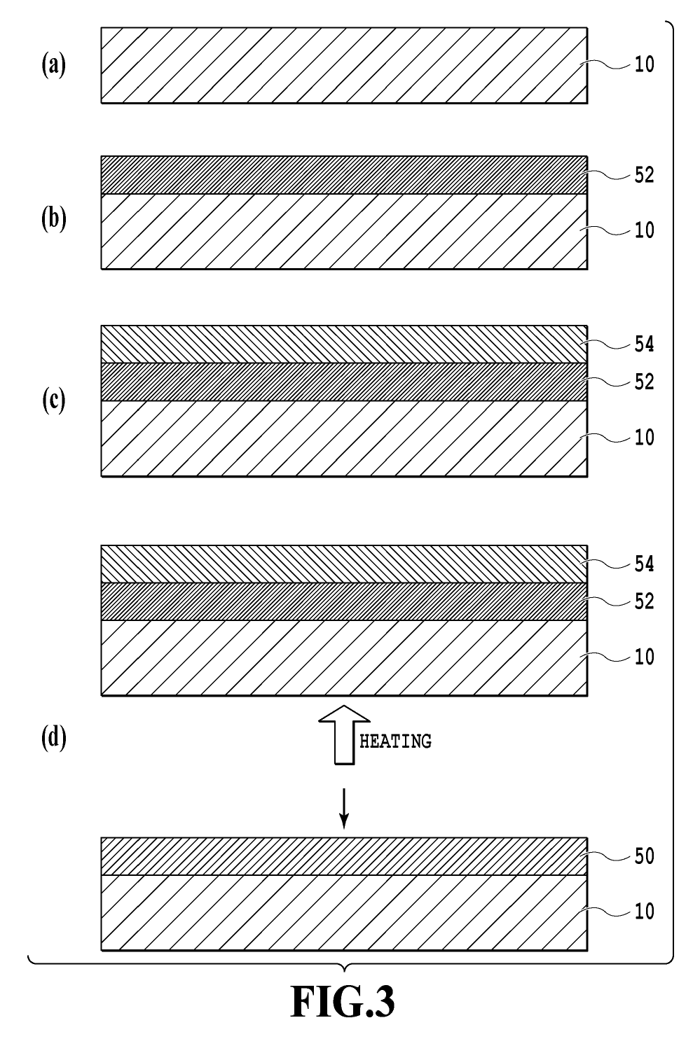

In the step (1), as shown in FIGS. 3(a) and 3(b), the substrate 10 is provided, and, on the substrate 10, the magnetic layer comprised of FePt or FePtRh is deposited as the first magnetic layer 52.

The substrate 10 may be various substrates having a smooth surface. For example, the substrate 10 may be formed from materials generally used in magnetic recording medium. Materials that can be used include a NiP-plated Al alloy, MgO single crystal, MgAl₂O₄, SrTiO₃, reinforced glass, crystallized glass, Si/SiO₂, etc.

The first magnetic layer 52 of the magnetic recording layer 50 is formed by depositing Fe and Pt as constituent elements of an ordered alloy, and optional Rh with a sputtering method.

By sputtering Fe and Pt, or Fe, Pt and Rh constituting the ordered alloy, the first magnetic layer 52 may be formed. A step of “sputtering” as used herein means only a step of causing atoms, clusters or ions to be ejected from a target by collision with ions having high energy, and does not mean that all elements included in the ejected atoms, clusters or ions are fixed onto a substrate to be deposited. In other words, a thin film obtained in the step of “sputtering” as used herein not necessarily includes elements arriving at the substrate to be deposited at a ratio of the amount as arrived. When the first magnetic layer 52 is formed by an ordered alloy FePt, a target comprising Fe and Pt at a predetermined ratio may be used. Alternatively, an Fe target and a Pt target may be used. Further, when the first magnetic layer 52 is formed by an ordered alloy FePtRh, a target comprising Fe, Pt and Rh at a predetermined ratio may be used. Alternatively, a target comprising Fe and Pt, and a Rh target may be used. Yet alternatively, each of Fe, Pt and Rh targets may be used. In either case, the ratio of each elements may be controlled by adjusting electric powers applied to respective targets.

In the step (2), as shown in FIG. 3(c), the second magnetic layer 54 is formed on the first magnetic layer 52 which is formed on the substrate 10. As the second magnetic layer, a magnetic layer comprised of FePtRh is deposited. When FePtRh is used as the material of the first magnetic layer in the step (1), in the second magnetic layer, FePtRh is used having a Rh content higher than the Rh content in FePtRh which is used in the first magnetic layer.

The second magnetic layer may be deposited by the same method as that in the instance of deposition of the first magnetic layer by use of FePtRh.

In the steps (1) and (2), each component of materials and parameters of film thickness in the first magnetic layer 52 and the second magnetic layer 54 is as follows.

When the film thickness of the first magnetic layer is denoted by t1, the atom % of each component of FePt or FePtRh in the first magnetic layer is denoted by Fe: x1 atom %, Pt: y1 atom % and Rh: z1 atom %, the film thickness of the second magnetic layer is denoted by t2, and the atom % of each component of FePtRh in the second magnetic layer is denoted by Fe: x2 atom %, Pt: y2 atom % and Rh: z2 atom %, an Fe/Pt ratio x2/y2=0.7-1.4, and preferably x1/y1=0.7-1.4. Further concentration of Rh is preferably z2: 3 atom %-15 atom %, and z1: 0 atom %-12 atom % (z2>z1). The film thickness of the first magnetic layer 52 and the second magnetic layer 54 is preferably t1: 0.5 nm-10 nm, and t2: 0.5 nm-10 nm. Meanwhile, as will be described later, the sequential order of the first magnetic layer and the second magnetic layer may be reversed.

In the step (3), as shown in FIG. 3(d), the substrate on which the first magnetic layer and the second magnetic layer are formed is heated to cause Rh to diffuse from the second magnetic layer toward the first magnetic layer to produce inclination of the Rh component in the magnetic recording layer 50. Heating temperature of the substrate is 400° C. or higher, preferably 400° C.-700° C. The heating time depends on a degree of intended inclination of a component, and is, for example, 1 sec-20 sec, and preferably 2 sec-10 sec. The heating of the substrate may be performed by use of a conventional technique that uses a lamp heater etc. in a heating chamber.

As the result that the inclination of the Rh component is produced by the diffusion of Rh toward the first magnetic layer, a Ku value changes in a film thickness direction of the magnetic recording layer by a concentration gradient of Rh. Therefore, the inclination of Ku may be realized. Further, Rh diffuses rapidly in FePt, and, therefore, is an additive material suitable for producing the inclination of a component.

Another manufacturing method for a magnetic recording medium is for a magnetic recording medium comprising at least a substrate and a magnetic recording layer, in which the magnetic recording layer comprises Fe, Pt and Rh, and composition of Rh in the magnetic recording layer changes in a film thickness direction of the magnetic recording layer. The method comprises: (i) a heating step of heating the substrate; (ii) a first deposition step of forming a first magnetic layer comprising Fe and Pt, or Fe, Pt and Rh on the heated substrate; and (iii) a second deposition step of forming a second magnetic layer comprising Fe, Pt and Rh on the first magnetic layer, the second magnetic layer, when the first magnetic layer comprises Rh, being formed so as to comprise Rh in concentration higher than that in the first magnetic layer.

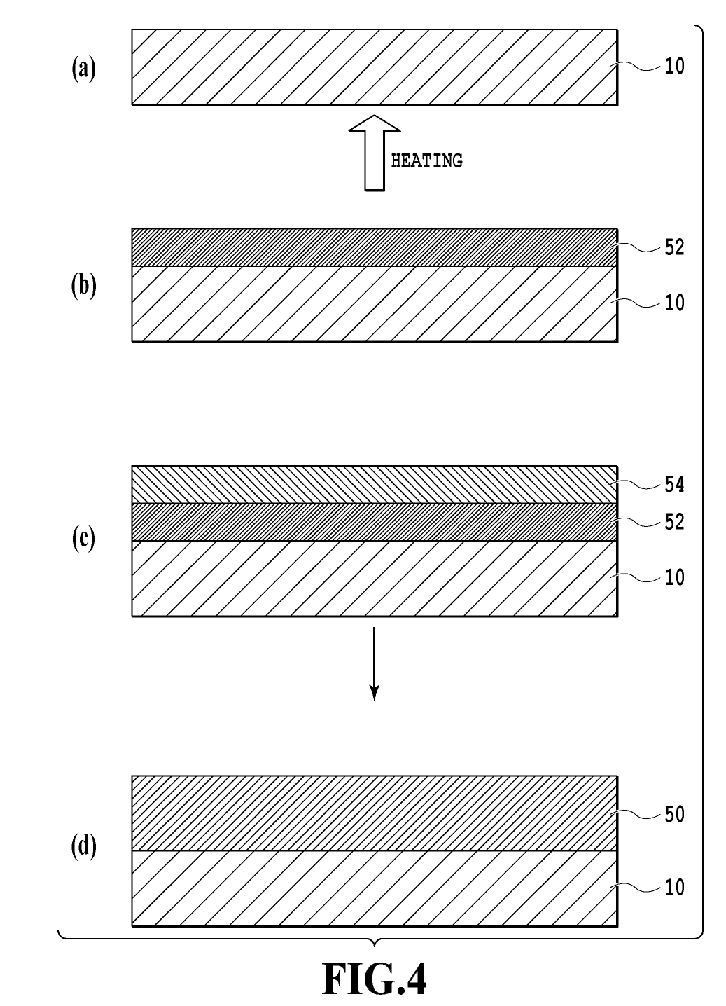

In the step (i), as shown in FIG. 4(a), the substrate 10 is heated. The upper limit of the heating temperature of a substrate is restricted mainly by heat resistant temperature of the substrate, and is 400° C. or higher, and preferably 400° C.-1000° C. The heating time is not particularly limited, as long as it is time capable of realizing the above described temperature. The heating of the substrate may be performed by use of a conventional technique that uses a lamp heater etc. in a heating chamber.

A deposition apparatus for mass-production of a magnetic recording medium has a configuration of aligning a plurality of vacuum deposition chambers. In manufacturing of the magnetic recording medium, by use of the apparatus, a substrate is put from a substrate putting chamber, and then a deposition step and a transfer step of the substrate are repeated at a particular timing, such as deposition, transfer of the substrate to an adjacent chamber, deposition of a subsequent layer and transfer of the substrate to an adjacent chamber, so as to deposit effectively a thin film of a multilayer structure. Further, as a magnetic recording medium, it becomes necessary to perform deposition for both surfaces of the substrate, and, therefore, each of deposition chambers has a structure of cathodes facing each other to perform deposition for both sides of the substrate at the same time. Accordingly, it is difficult to perform a heating and deposition simultaneously. In an instance of heating deposition in which deposition is performed with heating of a substrate, the substrate is heated with a lamp heater in a chamber lying just before a chamber for a layer carrying out the heating deposition, and the heating deposition is performed in the subsequent chamber by utilizing the heat.

Accordingly, in the step (i), first, the substrate 10 is heated in a chamber for heating to a predetermined temperature.

In the step (ii), as shown in FIG. 4(b), a first magnetic layer is deposited on the substrate heated to the predetermined temperature. The first magnetic layer is formed by depositing Fe and Pt as constituent elements of an ordered alloy, and optional Rh with a sputtering method. For example, by sputtering Fe and Pt, or Fe, Pt and Rh, the first magnetic layer 52 may be formed. The deposition is performed before the heated temperature falls to a particular temperature or lower, preferably to less than 420° C. Conditions such as a target and film thickness, and a procedure of deposition when the deposition of the first magnetic layer is performed, are the same as those described above.

In the step (iii), as shown in FIG. 4(c), on the first magnetic layer of the substrate on which the first magnetic layer is deposited, a second magnetic layer is deposited. The deposition is performed before the heated temperature falls to a particular temperature or lower, preferably to less than 400° C. For example, by sputtering Fe, Pt and Rh, the second magnetic layer 54 may be formed. In the second magnetic layer, when FePtRh is used as a material for the first magnetic layer in the step (ii), FePtRh having a Rh content higher than the Rh content in FePtRh which is used for the first magnetic layer, is used. Conditions such as a target and film thickness, and a procedure of deposition when the deposition of the second magnetic layer is performed, are the same as those described above.

When the second magnetic layer is deposited in the step (iii), the substrate has a predetermined temperature, and, therefore, Rh diffuses from the second magnetic layer into the first magnetic layer to form inclination of the Rh component in the magnetic recording layer 50. After the deposition of the second magnetic layer is performed, the substrate temperature is held for a predetermined time, or, if necessary, a cooling rate of the substrate is adjusted so that an intended inclination of the Rh component may be obtained. The adjustment of the cooling rate may be carried out in a cooling chamber, for example, by flowing inert gas such as Ar or N₂ to adjust the temperature in the cooling chamber.

A yet another manufacturing method for a magnetic recording medium is for a magnetic recording medium comprising at least a substrate and a magnetic recording layer, in which the magnetic recording layer comprising Fe, Pt and Rh, and composition of Rh in the magnetic recording layer changes in a film thickness direction of the magnetic recording layer. The method comprises: (A) a first deposition step of forming a first magnetic layer comprising Fe and Pt, or Fe, Pt and Rh with heating of the substrate from a back surface, and (B) a second deposition step of forming a second magnetic layer comprising Fe, Pt and Rh with heating of the substrate obtained in the first deposition step from a back surface, the second magnetic layer, when the first magnetic layer comprises Rh, being formed so as to comprising Rh in concentration higher than that in the first magnetic layer. Here, the term “back surface” means, in two surfaces on the substrate, when a thin film such as a magnetic layer is formed on one of the surfaces, a surface on the side on which the formation of the layer is not performed.

In the step (A), first, one side of the substrate 10, for example, the back surface is heated. The upper limit of the heating temperature of the substrate is restricted mainly by heat resistant temperature of the substrate, and is 400° C. or higher, preferably 400° C.-1000° C. The heating of the substrate may be performed by use of a conventional technique that uses a lamp heater etc. in a heating chamber.

Next, with heating of the substrate to a predetermined temperature, the first magnetic layer is formed on the surface opposite to the heated surface of the substrate, specifically, when the back surface of the substrate is heated, on the front surface side of the substrate. The first magnetic layer is formed by depositing Fe and Pt as an ordered alloy and optional Rh by a sputtering method. For example, by sputtering Fe and Pt, or Fe, Pt and Rh, the first magnetic layer 52 may be formed. The deposition is performed from a direction in which heat is not applied to the substrate, because the deposition is performed with heating the substrate. Conditions such as a target and film thickness, and a procedure of deposition when the deposition of the first magnetic layer is performed, are the same as those described above.

In the step (B), the second magnetic layer is deposited on the first magnetic layer of the substrate on which the first magnetic layer has been deposited. The deposition may be performed with holding the state of heating of the substrate on which the first magnetic layer has been deposited. For example, by sputtering Fe, Pt and Rh with heating the substrate, the second magnetic layer 54 may be formed on the first magnetic layer. When FePtRh is used as a material of the first magnetic layer in the step (A), the second magnetic layer uses FePtRh having a Rh content higher than the Rh content in FePtRh which is used in the first magnetic layer. Conditions such as a target and film thickness, and a procedure of deposition when the deposition of the second magnetic layer is performed, are the same as those described above.

When the first magnetic layer and the second magnetic layer are formed in the step (A) and the step (B), respectively, the substrate is heated to a predetermined temperature. Therefore, Rh diffuses from the second magnetic layer toward the first magnetic layer when the second magnetic layer is deposited, to form the inclination of the Rh component in the magnetic recording layer 50. If necessary, after the deposition of the second magnetic layer, the temperature of the substrate is kept for a predetermined time or the cooling rate of the substrate is adjusted so as to give an intended inclination of the Rh component. The adjustment of the cooling rate may be carried out in a cooling chamber, for example, by a stream of inert gas such as Ar or N₂ to adjust the temperature in the cooling chamber.

As described above, by laminating the second magnetic layer comprised of FePtRh on the first magnetic layer comprised of FePt or FePtRh and, subsequently, heating the substrate after depositing the first magnetic layer and the second magnetic layer, or depositing the first magnetic layer and the second magnetic layer on the substrate previously heated to a predetermined temperature, the inclination of the Rh component may be formed in the magnetic recording layer 50. In the manufacturing method for the magnetic recording medium, when the second magnetic layer composed of FePtRh is laminated on the first magnetic layer composed of FePtRh, the concentration of Rh in the second magnetic layer is set to be higher than that in the first magnetic layer.

As the result of the inclination of the Rh component in the magnetic recording layer, a magnetic recording layer having an inclined Ku may be achieved.

In the above description, such an example was used that the first magnetic layer 52 and the second magnetic layer 54 were formed in this order, but the second magnetic layer 54 and the first magnetic layer 52 may be formed in this order. In the latter case, it is possible to form the magnetic recording layer 50 having a concentration gradient in which the concentration of Rh reduces monotonically from the substrate 10 side of the magnetic recording layer 50 toward the protective layer 60 side.

Further, it is also possible to make various changes in a range in which the formation of the concentration gradient of Rh is not prevented. For example, another element may be added as an element constituting the magnetic recording layer in addition to Fe, Pt and Rh to adjust a magnetic property to an intended property. For example, Cu, Ag, Au, Mn or the like may also be added for the purpose of adjusting the Curie temperature Tc.

Further, in order to cause the magnetic recording layer 50 to have a granular structure, carbide, oxide, nitride or the like that constitutes a grain boundary, may further be added.

Moreover, the magnetic recording layer 50 may further comprise one or plurality of additional magnetic layers, in addition to the first magnetic layer 52 and the second magnetic layer 54. Each of one or a plurality of additional magnetic layers may have either a granular structure or a non-granular structure. For example, a laminated ECC (Exchange-coupled Composite) structure may be formed by sandwiching a coupling layer comprised of Ru or the like between the laminated structure comprised of the first magnetic layer 52 and the second magnetic layer 54 and the additional magnetic layer. Alternatively, a magnetic layer not including a granular structure may be provided on the upper part of a laminated structure of the first magnetic layer 52 and the second magnetic layer 54, as a continuous layer. The continuous layer includes a so-called cap layer.

For the magnetic recording medium, as described above, various layers may be provided optionally in addition to a magnetic recording layer. Hereinafter, these layers will be described. Meanwhile, the reference numbers referred to in the description below are those shown in FIG. 2.

An adhesion layer 20 that may optionally be provided is used for enhancing adhesion between a layer formed on the adhesion layer 20 and a layer formed under the adhesion layer 20. The layer formed under the adhesion layer 20 includes the substrate 10. Materials for forming the adhesion layer 20 include metals such as Ni, W, Ta, Cr and Ru, and alloys including the aforementioned meal. The adhesion layer 20 may be a single layer, or has a laminated structure of a plurality of layers. The adhesion layer may be formed by use of any process known in the art, such as a sputtering method or a vacuum deposition method.

A soft magnetic underlayer (not shown), which may be provided optionally, controls a magnetic flux from a magnetic head to improve properties in recording/reproducing of a magnetic recording medium. Materials for forming the soft magnetic underlayer include crystalline materials such as a NiFe alloy, a Sendust (FeSiAl) alloy and a CoFe alloy, microcrystalline materials such as FeTaC, CoFeNi and CoNiP, and amorphous materials including a Co alloy such as CoZrNb and CoTaZr. The optimal value of the film thickness of the soft magnetic underlayer depends on a structure and characteristics of a magnetic head for use in magnetic recording. When a soft magnetic underlayer is formed by continuous deposition with another layer, in view of a balance with productivity, a soft magnetic underlayer preferably has film thickness within a range of 10 nm-500 nm (both inclusive). The soft magnetic underlayer may be formed by use of any process known in the art, such as a sputtering method or a vacuum deposition method.

When the magnetic recording medium of the present invention is used in a thermally-assisted magnetic recording method, a heat-sink layer (not shown) may be provided. The heat-sink layer is a layer for effectively absorbing excess heat of the magnetic recording layer 50 generated in the thermally-assisted magnetic recording. The heat-sink layer may be formed by use of a material with a high heat conductivity and specific heat capacity. Such materials include a Cu simple substance, a Ag simple substance, a Au simple substance or alloy materials mainly composed of them. Here, “mainly composed of” means that a content of the material is 50 wt % or more. Further, from the viewpoint of strength or the like, the heat-sink layer may be formed by use of an Al—Si alloy, a Cu—B alloy, or the like. Moreover, the heat-sink layer may be formed by use of a Sendust (FeSiAl) alloy, a soft magnetic CoFe alloy, or the like. It is also possible to give, to the heat-sink layer, a function of concentrating a magnetic field in a perpendicular direction generated by the head on the magnetic recording layer 50 to thereby complement the function of the soft magnetic underlayer, as the result of using the soft magnetic material. An optimal value of the film thickness of the heat-sink layer changes depending on a heat quantity and heat distribution in the thermally-assisted magnetic recording as well as the layer structure of the magnetic recording medium and a thickness of each constituent layer. In a case of formation by continuous deposition with another layer, the film thickness of the heat-sink layer is preferably 10 nm or more and 100 nm or less, in view of a balance with productivity. The heat-sink layer may be formed by use of any process known in the art such as a sputtering method or a vacuum deposition method. In common cases, the heat-sink layer is formed by use of the sputtering method. The heat-sink layer may be provided between the substrate 10 and the adhesion layer 20, between the adhesion layer 20 and the underlayer 30, and the like, in consideration of the properties required for the magnetic recording medium.

The underlayer 30 is a layer for controlling crystallinity and/or crystalline orientation of the seed layer 40 formed on the upper side. The underlayer 30 may be a single layer or multiple layers. The underlayer 30 is preferably non-magnetic. A non-magnetic material used for forming the underlayer 30 includes Pt metal, Cr metal, or an alloy obtained by adding at least one kind of metal selected from the group consisting of Mo, W, Ti, V, Mn, Ta and Zr to Cr as a main component. The underlayer 30 may be formed by use of any process known in the art, such as a sputtering method.

The function of the seed layer 40 is to control a particle size of magnetic crystal grains and crystalline orientation in the magnetic recording layer 50 as the upper layer. The seed layer 40 may be given a function of securing adhesion between a layer under the seed layer 40 and the magnetic recording layer 50. Further, another layer such as an intermediate layer may be disposed between the seed layer and the magnetic recording layer 50. When the intermediate layer or the like is disposed, it bears the function of controlling the particle size and crystalline orientation of magnetic crystal grains in the magnetic recording layer 50 by controlling the particle size and crystalline orientation of crystal grains in an intermediate layer or the like. The seed layer 40 is preferably nonmagnetic. The material of the seed layer 40 may be selected suitably in accordance with the material of the magnetic recording layer 50. More specifically, the material of the seed layer 40 is selected in accordance with the material of magnetic crystal grains in the magnetic recording layer. For example, when the magnetic crystal grain in the magnetic recording layer 50 is formed from an L1ₒ type ordered alloy, preferably the seed layer 40 is formed by use of a NaCl type compound. Preferably, the seed layer 40 is formed by use of oxide such as MgO or SrTiO₃, or nitride such as TiN. The seed layer 40 may also be formed by laminating a plurality of layers formed from the above-described material. From the viewpoint of improving crystallinity of magnetic crystal grains in the magnetic recording layer 50 and improving productivity, the seed layer has film thickness of 1 nm-60 nm, preferably film thickness of 1 nm-20 nm. The seed layer 40 may be formed by use of any process known in the art such as a sputtering method.

Layers or a layer known in the art such as an adhesion layer, a soft magnetic underlayer, a heat-sink layer, an underlayer and/or a seed layer to be formed prior to the deposition of the magnetic recording layer on the substrate may be deposited prior to the deposition step of the first magnetic layer, in the manufacturing method for the magnetic recording medium.

The protective layer 60 may be formed by use of a material commonly used in the art of a magnetic recording medium. Specifically, the protective layer 60 may be formed by use of a non-magnetic metal such as Pt, a carbon-based material such as diamond-like carbon, or a silicon-based material such as silicon nitride. Further, the protective layer 60 may be a single layer, or may have a laminated structure. The protective layer 60 of a laminated structure, for example, may be a laminated structure of two types of carbon-based materials having different properties, a laminated structure of a metal and a carbon-based material, or a laminated structure of a metal oxide film and a carbon-based material. The protective layer 60 may be formed by use of any process known in the art, such as a CVD method, a sputtering method (including a DC magnetron sputtering method etc.) and a vacuum deposition method.

Further, the magnetic recording medium of the present invention may optionally include a liquid-lubricant layer (not shown) on the protective layer 60. The liquid-lubricant layer may be formed by use of a material commonly used in the art of magnetic recording medium. Materials of the liquid-lubricant layer include, for example, perfluoropolyether-based lubricants, etc. The liquid-lubricant layer may be formed, for example, by use of a coating method such as a dip coating method or a spin coating method.

Layers or a layer known in the art such as a protective layer and/or a liquid-lubricant layer to be formed on the magnetic recording layer 50 may be deposited after the deposition step of the magnetic recording layer 50, that is, after the step (1)-(3) or the step (i)-(iii), in the manufacturing method for the magnetic recording medium.

The magnetic recording medium is a magnetic recording medium that comprises at least a substrate and a magnetic recording layer, in which the magnetic recording layer comprises Fe, Pt and Rh, wherein the composition of Rh in the magnetic recording layer changes in a film thickness direction of the magnetic recording layer. This magnetic recording medium may be produced by a step that allows mass-production by the above-described manufacturing method for the magnetic recording medium.

### EXAMPLES

### Example 1

In Example 1, the relationship between the concentration of X in FePtX (X was Rh, Cu or Ru) and Ku was examined.

A chemically reinforced glass substrate having a smooth surface (N-10 glass substrate, manufactured by HOYA) was washed to prepare a substrate 10. The substrate 10 after washing was introduced into an in-line type sputtering apparatus. By a DC magnetron sputtering method using a pure Ta target in Ar gas of 0.5 Pa in pressure, a Ta adhesion layer 20 of 5 nm in film thickness was formed. Substrate temperature during forming the Ta adhesion layer was room temperature (25° C.). Sputtering electric power during forming the Ta adhesion layer was 100 W.

Then, by a DC magnetron sputtering method using a pure Cr target in Ar gas of 0.5 Pa in pressure, a Cr underlayer 30 of 20 nm in film thickness was obtained. Substrate temperature during forming the Cr underlayer 30 was room temperature (25° C.). Sputtering electric power during forming the Cr underlayer 30 was 300 W.

Then, by an RF magnetron sputtering method using a MgO target in Ar gas of 0.1 Pa in pressure, a MgO seed layer 40 of 5 nm in film thickness was formed. Substrate temperature during forming the MgO seed layer 40 was room temperature (25° C.). Sputtering electric power during forming the MgO seed layer 40 was 200 W.

Then, a laminated body in which the MgO seed layer had been formed was heated to 430° C., and a magnetic recording layer consisting of FePtX (X was Rh, Ru or Cu) was formed by a DC magnetron sputtering method using an FePt target in Ar gas of 0.6 Pa in pressure. The film thickness of the magnetic recording layer was 10 nm. Electric power applied to an FePt target during forming the magnetic recording layer was 300 W. Electric power applied to Rh, Ru and Cu targets, respectively, were as shown in Tables 1-3. The content of component X in the produced magnetic recording medium was shown in Tables 1-3 below. Contents of Fe and Pt, when the addition amount of X is 0, are 55 atom % of Fe and 45 atom % of Pt, and, as X is added, the X addition amount increases while the Fe/Pt ratio is kept. Meanwhile, the addition amount of Fe and Pt, and the addition amount of the element X in Tables are represented by atom % based on the total atoms.

Finally, by a DC sputtering method using a Pt target in Ar gas of 0.5 Pa in pressure, a Pt protective layer 60 of 5 nm in film thickness was formed to give a magnetic recording medium. The substrate temperature during forming the protective layer was room temperature (25° C.). Sputtering power during the formation of the Pt protective layer 60 was 50 W.

Dependency of spontaneous magnetization on a magnetic field application angle was evaluated by use of a PPMS apparatus (Physical Property Measurement System, manufactured by Quantum Design), and magnetic anisotropy constants Ku at room temperature and at 230° C. were determined. In the determination of the magnetic anisotropy constant Ku, techniques described in R. F. Penoyer, “Automatic Torque Balance for Magnetic Anisotropy Measurements,” The Review of Scientific Instruments, pp. 711-714, Vol. 30, No. 8, August 1959, or in Soshin CHIKAZUMI, “Physics of Ferromagnetism” (vol. 2) pp. 10-21, Shokabo Co., Ltd. were used (see R. F. Penoyer, “Automatic Torque Balance for Magnetic Anisotropy Measurements,” The Review of Scientific Instruments, 711-714, vol. 30, No. 8, August 1959; and Soshin Chikazumi, “Physics of Ferromagnetism” (vol. 2) 10-21, Shokabo Co., Ltd.). Measurement results were shown together in Tables 1-3.

TABLE 1
Rh addition

| | Applied | | | |
|---|---|---|---|---|
| Addition | electric | | Ku at room | Ku at |
| amount of | power | Tc | temperature | 230° C. |
| Rh | (W) | (° C.) | (erg/cc) | (erg/cc) |
| 0.0 | 0 | 470 | 3.19E+07 | 1.72E+07 |
| 5.7 | 70 | 341 | 3.05E+07 | 1.07E+07 |
| 7.8 | 80 | 309 | 2.73E+07 | 7.61E+06 |
| 9.6 | 90 | 260 | 2.48E+07 | 3.16E+06 |
| 11.8 | 100 | 214 | 2.03E+07 | |

TABLE 2
Ru addition

| | Applied | | | |
|---|---|---|---|---|
| Addition | electric | | Ku at room | Ku at |
| amount of | power | Tc | temperature | 230° C. |
| Ru | (W) | (° C.) | (erg/cc) | (erg/cc) |
| 0.0 | 0 | 470 | 3.19E+07 | 1.72E+07 |
| 1.9 | 60 | 393 | 2.91E+07 | 1.29E+07 |
| 6.1 | 100 | 365 | 2.11E+07 | 8.39E+06 |
| 11.6 | 140 | 272 | 1.70E+07 | 2.87E+06 |

TABLE 3
Cu addition

| | Applied | | | |
|---|---|---|---|---|
| Addition | electric | | Ku at room | Ku at |
| amount of | power | Tc | temperature | 230° C. |
| Cu | (W) | (° C.) | (erg/cc) | (erg/cc) |
| 0.0 | 0 | 470 | 3.19E+07 | 1.72E+07 |
| 3.9 | 60 | 408 | 2.62E+07 | 1.22E+07 |
| 9.5 | 80 | 375 | 2.05E+07 | 8.48E+06 |
| 15.3 | 100 | 342 | 1.40E+07 | 4.94E+06 |

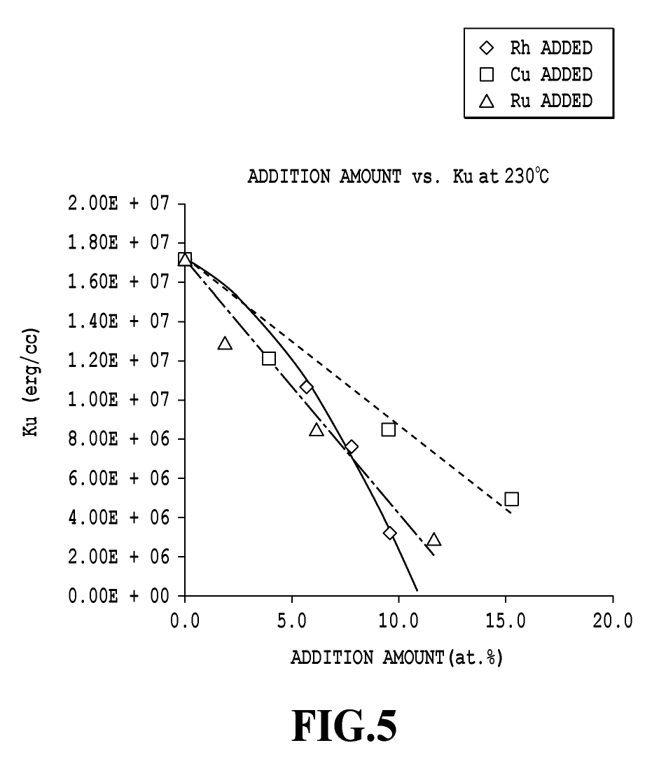

A part of the above-described results were shown in a graph in FIG. 5. The graph in FIG. 5 shows the relationship between addition concentration when Rh, Cu or Ru is added to FePt and Ku (230° C.). In heat-assisted magnetic recording, recording is performed with heating of a magnetic recording layer, and thus, magnetic properties that influences on recording procedure are those during heating. Consequently, as an example, data at 230° C. are compared. From the graph, the FePt magnetic recording layer to which Rh or Ru is added shows larger lowering of Ku with the increase in the addition amount, as compared with the instance of Cu, and possible to say as materials capable of producing easily the inclination of Ku.

### Example 2

In Example 2, the relationship between heating deposition time of FePtX (X was Rh or Ru), and diffusion distance and diffusion coefficient of the component X, was examined. Meanwhile, Example 2 corresponds to an example of a manufacturing method for a magnetic recording medium in which heating is performed after the deposition of a first magnetic layer and a second magnetic layer.

A Si substrate, SiO₂, FePt (20 nm) and FePtX (20 nm) were formed sequentially to give a magnetic recording medium. The deposition was performed at room temperature. After that, post-heating treatments were performed at temperature for heating time shown in Table 4. X in FePtX is Rh or Ru. Contents of Fe and Pt in FePtX are 50 atom % of Fe and 40 atom % of Pt. Addition amounts of Rh and Ru are 10 atom %, respectively, (the addition amount of each element is based on the total atoms).

The concentration, diffusion distance and diffusion coefficient of the addition material X were determined according to the procedure below.

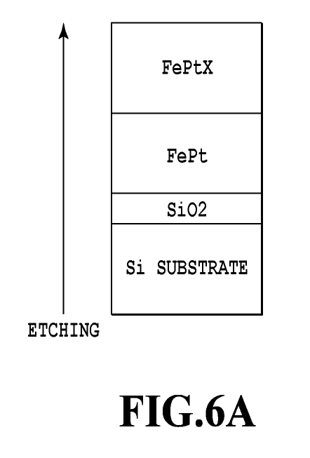

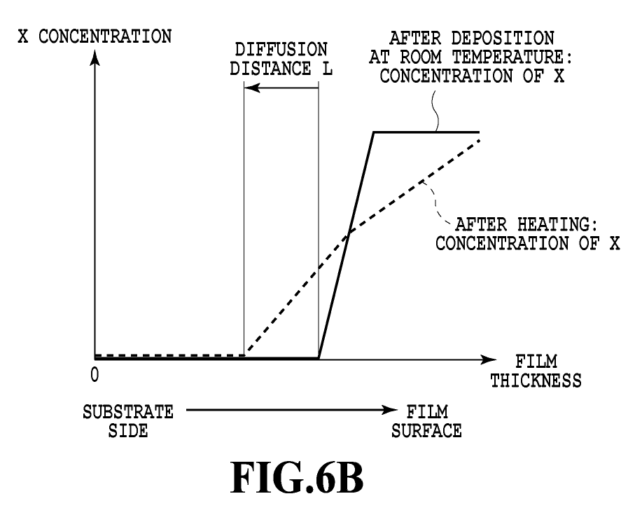

As shown in FIG. 6A, an FePt film and an FePtX film deposited at room temperature were etched from a substrate side to measure a concentration profile of the added element X in a thickness direction.

At the same time, concentration profiles of Fe and Pt were also measured to identify the interface between SiO₂ and an FePt film, to set the thickness of the point as zero.

After carrying out of the post-heating treatment at temperatures T (400, 500 and 600° C.) for heating treatment time t (sec), a concentration profile of X after heating is measured by the similar way to above.

A thickness at which X was detected before heating treatment was defined as the base of diffusion distance L, and the difference between this base of thickness and the thickness at which X was detected after the heat treatment was defined as diffusion distance L. The relationship between the diffusion distance L and diffusion coefficient D is represented by Formula 1 below, and thus, D was calculated from experimentally determined L and t.

L(t)=2\sqrt{Dt} [Formula 1]

In a sample deposited at room temperature, the element X has not diffused. On the other hand, in a sample after heating, the element X has diffused toward the first magnetic layer side and thus, a distance at which the element X is detected moves to the substrate side, as compared with the sample deposited at room temperature. The difference between distances at which the element X was detected was defined as the diffusion distance L (FIG. 6B).

For samples before and after heating, concentration profiles of the element X in depth direction were evaluated by secondary ion mass spectrometry (SIMS), and, according to the above-described procedure, the diffusion distance was determined and the diffusion coefficient was calculated. Results were shown together in Tables 4 and 5.

TABLE 4

| | Heating | Heating | Diffusion | Diffusion |
|---|---|---|---|---|
| | temperature | time | distance: L | coefficient: D |
| Material | (° C.) | (sec) | (nm) | (nm²/sec) |
| Rh | 400 | 20 | 9.0 | 1.013 |
| Rh | 500 | 20 | 13.3 | 2.211 |
| Rh | 600 | 20 | 17.5 | 3.828 |
| Ru | 400 | 180 | 3.0 | 0.013 |

TABLE 5

| | Rh diffusion | Ru diffusion |
|---|---|---|
| | coefficient | coefficient |
| Temperature | (nm²/sec) | (nm²/sec) |
| 400° C. | 1.013 | 0.013 |
| 500° C. | 2.211 | — |
| 600° C. | 3.828 | — |

From the above-described results, it is known that Rh is an element that diffuses easier into FePt as compared with Ru.

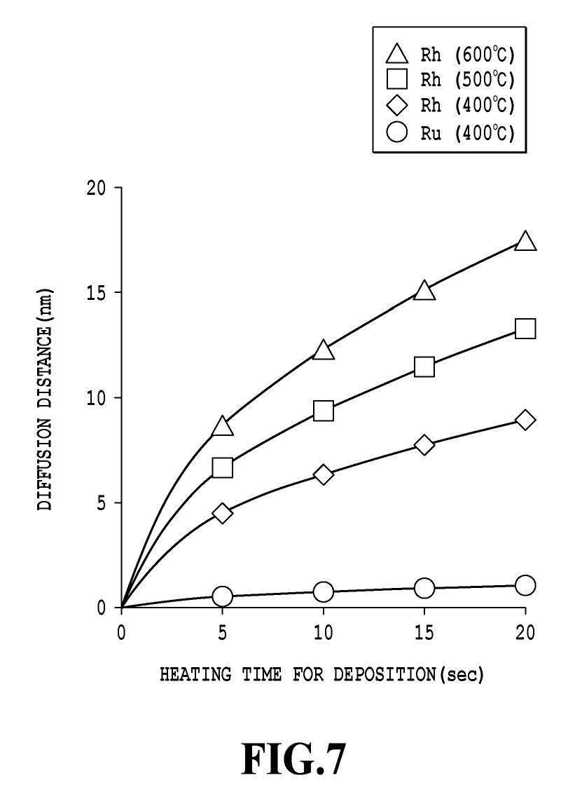

The graph in FIG. 7 is a graph showing the relationship between heating time t and diffusion distance L calculated from the diffusion coefficient D. It is known that Ru diffuses hardly, and that Rh may be diffused in 6 nm or longer at 500° C. for 5 sec.

### Example 3

Example 3 is an example of a manufacturing method for a magnetic recording medium wherein, after heating a substrate, a first magnetic layer and a second magnetic layer are deposited.

First, in the similar way to Example 1, a substrate, on which formation up to a seed layer has been performed, is produced. Then, when a magnetic recording layer in which a Rh component in FePtRh inclines, is formed, the substrate on which layers up to the seed layer has been formed is heated to predetermined temperature in a heating chamber. The predetermined temperature has a numerical value that is experimentally determined from temperature to be held in deposition, as will be described later. After that, in a subsequent deposition chamber, FePt (Fe addition amount: 55 atom %, Pt addition amount: 45 atom % (the addition amount of each of elements was based on the total atoms)), is formed in 2 nm. Then, the substrate is transferred to the subsequent chamber, and FePtRh (Fe addition amount: 50 atom %, Pt addition amount: 40 atom %, Rh addition amount: 10 atom % (the addition amount of each of elements was based on the total atoms)), is deposited in 7 nm. For example, from the graph in FIG. 7 of Example 2, when a substrate temperature is 400° C., time necessary for Rh to diffuse in 2 nm or longer may be estimated to be around 2 sec. Accordingly, the heating temperature in the heating chamber and a cooling rate in a deposition chamber are adjusted so that a state having 400° C. or higher is kept for sec or longer in conditions for deposition of FePtRh (temperature and time after deposition, including deposition time). The adjustment method of cooling rate may be performed in a cooling chamber, for example, by flowing inert gas such as Ar or N₂ to change the temperature in the chamber. Further, a holding temperature and time after the deposition of FePtRh may be adjusted optionally from the relationship between the heating time (t) and the diffusion distance (L) obtained in Example 2.

Further, after the deposition of a magnetic recording layer, a carbon protective layer is deposited, and, in a state of high substrate temperatures, properties of the carbon protective layer deteriorate. Therefore, the temperature of the substrate was lowered in the cooling chamber, and then formed a carbon protective layer. In addition, if necessary, a lubricating layer is formed.

A magnetic recording medium comprising a magnetic recording layer in which a Rh component in FePtRh inclines, may be formed by the above-described procedure.

### Example 4

Example 4 is an example of an instance in which heating of a substrate and deposition are performed at the same time.

A chemically reinforced glass substrate having a smooth surface (N-10 glass substrate, manufactured by HOYA) was washed to prepare a non-magnetic substrate. The washed non-magnetic substrate was introduced into a sputtering apparatus. By a DC magnetron sputtering method using a Ta target arranged at a position of 120 mm from the substrate in Ar gas of 0.50 Pa in pressure, a Ta adhesion layer of 5 nm in film thickness was formed. Electric power applied to the target was 100 W.

Then, by a DC magnetron sputtering method using a Cr target arranged at a position of 120 mm from the substrate in Ar gas of 0.28 Pa in pressure, a Cr underlayer of 20 nm in thickness was formed thereby obtaining a substrate. Electric power applied to the target was 300 W.

Then, by an RF magnetron sputtering method using a MgO target arranged at a position of 165 mm from the substrate in Ar gas of 0.1 Pa in pressure, a MgO seed layer of 5 nm in film thickness was formed to the laminated body wherein the Cr underlayer had been formed. An electric power applied to the target was 200 W. The temperature of the substrate on this period was room temperature (25° C.)

Then, the laminated body in which the seed layer was formed was heated to 430° C., and, with the substrate temperature held at 430° C., an FePt magnetic recording layer of 2 nm in film thickness was formed by a DC magnetron sputtering method using an FePt target arranged at a position of 165 mm from the substrate in Ar gas of 1.00 Pa in pressure. As an upper layer thereof, in a state of the substrate temperature at 430° C., an FePtRh magnetic recording layer of nm in film thickness was formed by a DC magnetron sputtering method using an FePt target and a Rh target. At this time, electric power applied to the FePt target was 300 W, and electric power applied to the Rh target was 100 W. Deposition time of the FePtRh layer at this time was 60 sec. Meanwhile, heating of the substrate was performed with a lamp heater from the back surface on the side opposite to the front surface on which a magnetic layer was formed.

Finally, by a DC magnetron sputtering method using a Pt target and a Ta target in Ar gas of 0.5 Pa in pressure, a protective layer that was a laminated body of a Pt film of 5 nm in film thickness and a Ta film of 5 nm in film thickness, was formed to give a magnetic recording medium. The substrate temperature in the formation of the protective layer was room temperature (25° C.). Sputtering power in the formation of the Pt film and the Ta film was 100 W.

By the above-described method, Rh in an upper layer may be diffused toward a lower layer to produce the concentration inclination of Rh.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. All of the patent applications and documents cited herein are incorporated herein by reference in their entirety.

What is claimed is:

1. A manufacturing method for a magnetic recording medium comprising at least a substrate and a magnetic recording layer, said magnetic recording layer comprising Fe, Pt and Rh, and composition of Rh in said magnetic recording layer changing in a film thickness direction of the magnetic recording layer, comprising:
(1) a first deposition step of forming a first magnetic layer comprising Fe and Pt, or Fe, Pt and Rh;
(2) a second deposition step of forming a second magnetic layer comprising Fe, Pt and Rh, the step forming the second magnetic layer, when said first magnetic layer comprises Rh, so as to comprise Rh in concentration higher than that in the first magnetic layer; and
(3) subsequent to the first deposition step and the second deposition step, a heating step of the substrate on which the first and second magnetic layers have been formed.

2. The manufacturing method for a magnetic recording medium according to claim 1, wherein heating temperature in said heating step in (3) is 400° C. or higher.

3. A magnetic recording medium manufactured by the manufacturing method according to claim 1.

4. A magnetic recording medium manufactured by the manufacturing method according to claim 2.

5. A manufacturing method for a magnetic recording medium comprising at least a substrate and a magnetic recording layer, said magnetic recording layer comprising Fe, Pt and Rh, and composition of Rh in said magnetic recording layer changing in a film thickness direction of the magnetic recording layer, comprising:
(i) a heating step of heating said substrate;
(ii) a first deposition step of forming a first magnetic layer comprising Fe and Pt, or Fe, Pt and Rh; and
(iii) a second deposition step of forming a second magnetic layer comprising Fe, Pt and Rh, the step forming the second magnetic layer, when said first magnetic layer comprise Rh, so as to comprise Rh in concentration higher than that in the first magnetic layer,
wherein the heating step is performed prior to the first deposition step and the second deposition step.

6. The manufacturing method for a magnetic recording medium according to claim 5, wherein temperature of heating the substrate in said heating step in (i), is 400° C. or higher.

7. A magnetic recording medium manufactured by the manufacturing method for a magnetic recording medium according to claim 5.

8. A magnetic recording medium manufactured by the manufacturing method for a magnetic recording medium according to claim 6.

9. A manufacturing method for a magnetic recording medium comprising at least a substrate and a magnetic recording layer, said magnetic recording layer comprising Fe, Pt and Rh, and composition of Rh in said magnetic recording layer changing in a film thickness direction of the magnetic recording layer, comprising:
(A) a first deposition step of forming a first magnetic layer comprising Fe and Pt, or Fe, Pt and Rh with heating of a substrate from a back surface; and
(B) a second deposition step of forming a second magnetic layer comprising Fe, Pt and Rh with heating from a back surface, the step forming the second magnetic layer, when said first magnetic layer comprises Rh, so as to comprise Rh in concentration higher than that in the first magnetic layer.

10. The manufacturing method for a magnetic recording medium according to claim 9, wherein temperature of heating of the substrate in said (A) and said (B) is 400° C. or higher.

11. A magnetic recording medium manufactured by the manufacturing method for a magnetic recording medium according to claim 9.

12. A magnetic recording medium manufactured by the manufacturing method for a magnetic recording medium according to claim 10.
